(19) United States
(12) Patent Application Publication
(10) Pub. No.: US 2024/0203877 A1
(43) Pub. Date: Jun. 20, 2024

(54) SEMICONDUCTOR STRUCTURE AND FORMATION METHOD THEREOF

(71) Applicant: Semiconductor Manufacturing International (Shanghai) Corporation, Shanghai (CN)

(72) Inventors: Bo SU, Shanghai (CN); Hailong YU, Shanghai (CN)

(21) Appl. No.: 18/535,825

(22) Filed: Dec. 11, 2023

(30) Foreign Application Priority Data
Dec. 16, 2022 (CN) 202211637566.6

(51) Int. Cl. H01L 23/528; H01L 21/8238; H01L 27/092; H01L 29/06; H01L 29/423; H01L 29/66; H01L 29/775; H01L 29/786

(52) U.S. Cl. CPC H01L 23/5283; H01L 21/823807; H01L 21/823871; H01L 27/092; H01L 29/0673; H01L 29/42392; H01L 29/66439; H01L 29/775; H01L 29/78696

(57) ABSTRACT

A semiconductor structure and a formation method of the semiconductor structure are provided in the present disclosure. The semiconductor structure includes a substrate, including a first device region and a second device region; a first device layer on the substrate, where a first transistor at the first device region is in the first device layer; a second device layer on the first device layer, where a second transistor at the second device region is in the second device layer, and projections of the first transistor and the second transistor on a surface of the substrate are non-overlapped with each other; and an electrical interconnection structure in the first device layer and the second device layer, where the electrical interconnection structure is electrically connected to each of the first transistor and the second transistor.

### CROSS-REFERENCE TO RELATED APPLICATION

This application claims the priority of Chinese Patent Application No. 202211637566.6, filed on Dec. 16, 2022, the content of which is incorporated herein by reference in its entirety.

### TECHNICAL FIELD

The present disclosure generally relates to the field of semiconductor manufacturing and, more particularly, relates to a semiconductor structure and a formation method thereof.

### BACKGROUND

With development of semiconductor technology, the process and structure of field effect transistor (FET) devices have continued to evolve from initial planar transistors to three-dimensional fin transistors. On such basis, gate-all-around transistors are developed, which may realize desirable transistor channel control, further reduce device size and improve device integration.

In recent years, CFET (complementary-FET) transistors have gained more popularity due to ultra-high integration. By stacking N-type metal-oxide semiconductor (NMOS) transistors and P-type metal-oxide semiconductor (PMOS) transistors vertically, CFET transistors greatly reduce the distances between the NMOS transistors and the PMOS transistors, which may make full use of three-dimensional space, greatly reduce the device areas, and improve transistor integration.

However, with continuous size reduction of transistor devices, the parasitic capacitance between the transistor structures in the devices is excessively large, which has become an important factor limiting device performance.

### SUMMARY

One aspect of the present disclosure provides a semiconductor structure. The semiconductor structure includes a substrate, including a first device region and a second device region; a first device layer on the substrate, where a first transistor at the first device region is in the first device layer; a second device layer on the first device layer, where a second transistor at the second device region is in the second device layer, and projections of the first transistor and the second transistor on a surface of the substrate are non-overlapped with each other; and an electrical interconnection structure in the first device layer and the second device layer, where the electrical interconnection structure is electrically connected to each of the first transistor and the second transistor.

Optionally, a conductivity type of the first transistor is opposite to a conductivity type of the second transistor; the first transistor is an N-channel metal-oxide semiconductor (NMOS) transistor, and the second transistor is a P-channel metal-oxide semiconductor (PMOS) transistor; and/or a spacing range between the first transistor and the second transistor is from about 20 nanometers to about 100 nanometers.

Optionally, the first transistor includes a first channel structure extending along a first direction and a first gate structure extending along a second direction; the first gate structure is on a surface of the first channel structure; and the second direction is perpendicular to the first direction; and the second transistor includes a second channel structure extending along the first direction and a second gate structure extending along the second direction; and the second gate structure is on a surface of the second channel structure.

Optionally, the first channel structure includes a plurality of first channel layers overlapped with each other along a direction perpendicular to the surface of the substrate, and the first gate structure surrounds a surface of each first channel layer; and the second channel structure includes a plurality of second channel layers overlapped with each other along the direction perpendicular to the surface of the substrate, and the second gate structure surrounds a surface of each second channel layer; and/or the electrical interconnection structure includes a first plug on the first gate structure, a second plug on the second gate structure, and a first electrical connection structure electrically connected to each of the first plug and the second plug; and the first gate structure and the second gate structure are electrically connected with each other through the first plug, the second plug and the first electrical connection structure.

Optionally, the first electrical connection structure is in the second device layer; the first plug is in the first device layer and the second device layer; and the second plug is in the second device layer; and/or the first plug passes through the substrate, the second plug passes through the first device layer and the substrate, and the first electrical connection structure is on the surface of the substrate.

Optionally, the first transistor further includes a first source electrode and a first drain electrode on two sides of the first gate structure; and the second transistor further includes a second source electrode and a second drain electrode on two sides of the second gate structure.

Optionally, the semiconductor structure further includes at first electrical contact structure electrically connected to the first source electrode; a second electrical contact structure electrically connected to the first drain electrode; a third electrical contact structure electrically connected to the second source electrode; and a fourth electrical contact structure electrically connected to the second drain electrode; and/or a third plug on the second electrical contact structure, a fourth plug on the third electrical contact structure, and a second electrical connection structure electrically connected to each of the third plug and the fourth plug, where the second electrical contact structure and the third electrical contact structure are electrically connected with each other through the third plug, the fourth plug and the second electrical connection structure.

Optionally, the second electrical connection structure is in the second device layer, the third plug is in the first device layer and the second device layer, and the fourth plug is in the second device layer; and/or the third plug passes through the substrate, the fourth plug passes through the first device layer and the substrate, and the second electrical connection structure is on the surface of the substrate.

Optionally, the semiconductor structure further includes an upper electrical interconnection layer on a surface of the second device layer.

Optionally, the second electrical connection structure is in the second device layer, and the upper electrical interconnection layer is electrically connected to the second electrical connection structure through a seventh plug; or the second electrical connection structure is on the surface of the second device layer.

Optionally, the semiconductor structure further includes a source connection plug passing through the substrate, where the first electrical contact structure is electrically connected to the source connection plug through an embedded power rail.

Optionally, the substrate further includes a third device region; and the semiconductor structure further includes a third transistor at the third device region and in the first device layer, where projections of the third transistor and the second transistor on the surface of the substrate are partially overlapped with each other; and/or the third transistor includes a third channel structure and a third gate structure crossing the third channel structure; and a third source electrode and a third drain electrode on two sides of the third gate electrode structure; and/or a conductivity type of the third transistor is same as a conductivity type of the first transistor.

Optionally, the semiconductor structure further includes a fifth electrical contact structure electrically connected to the third source electrode; and a sixth electrical contact structure electrically connected to the third drain electrode, where projections of the fifth electrical contact structure and the fourth electrical contact structure on the substrate surface are at least partially overlapped with each other.

Optionally, the semiconductor structure further includes an upper electrical interconnection layer; a fifth plug on the third gate structure, where the third gate structure is electrically connected to the upper electrical interconnection layer through the fifth plug; and a sixth plug is on the sixth electrical contact structure, where the sixth electrical contact structure is electrically connected to the upper electrical interconnection layer through the sixth plug; and/or a source connection plug passing through the substrate, where the fifth electrical contact structure is electrically connected to the source connection plug through an embedded power rail.

Optionally, the semiconductor structure further includes a dielectric layer between the first device layer and the second device layer.

Another aspect of the present disclosure provides a formation method of a semiconductor structure. The method includes forming a substrate, where the substrate includes a first device region and a second device region; forming a first device layer on the substrate, where a first transistor at the first device region is in the first device layer; forming a second device layer on the first device layer, where a second transistor at the second device region is in the second device layer, and projections of the first transistor and the second transistor on a surface of the substrate are non-overlapped with each other; forming an electrical interconnection structure, where the first transistor is electrically connected to the second transistor through the electrical interconnection structure; and forming a dielectric layer between the first device layer and the second device layer.

Optionally, forming the second device layer includes providing a second substrate, where the second substrate includes a first surface and a second surface which are opposite to each other; forming the second device layer on the first surface, where the second transistor is in the second device layer; after forming the second device layer, bonding the first side with the first device layer, such that the second transistor is at the second device region of the first substrate; and after bonding the first side with the first device layer, removing the second substrate.

Optionally, an initial bonding layer is formed on a surface of one of the first device layer and the second device layer or surfaces of both the first device layer and the second device layer; and after bonding the first side with the first device layer, the initial bonding layer forms a bonding dielectric layer between the first device layer and the second device layer.

Optionally, the first transistor includes a first channel structure extending along a first direction and a first gate structure extending along a second direction; the first gate structure is on a surface of the first channel structure; and the second direction is perpendicular to the first direction; and the second transistor includes a second channel structure extending along the first direction and a second gate structure extending along the second direction; and the second gate structure is on a surface of the second channel structure.

Optionally, the first channel structure includes a plurality of first channel layers overlapped with each other along a direction perpendicular to the surface of the substrate, and the first gate structure surrounds a surface of each first channel layer; and the second channel structure includes a plurality of second channel layers overlapped with each other along the direction perpendicular to the surface of the substrate, and the second gate structure surrounds a surface of each second channel layer.

Compared with the existing technology, the technical solutions provided by the present disclosure may achieve at least the following beneficial effects.

In the semiconductor structure provided in technical solutions of the present disclosure, the second transistor may be at an upper layer above the first transistor; and the projections of the first transistor and the second transistor on the surface of the substrate may be non-overlapped with each other; that is, the first transistor and the second transistor may be arranged in a staggered manner along the direction in parallel with the substrate. Therefore, the space between the first transistor and the second transistor may be additionally provided, the parasitic capacitance between the first transistor and the second transistor may be reduced, thereby improving device performance. Meanwhile, the staggered arrangement of the first transistor and the second transistor may provide more wiring space for the electrical connection between the first transistor and the second transistor, which may improve process window and reduce process defect.

Furthermore, the projections of the third transistor and the second transistor, which are at a same layer as the first transistor, on the substrate surface may be partially overlapped with each other; and the projections of the fifth electrical contact structure on the third transistor and the fourth electrical contact structure on the second transistor on the substrate surface may be at least partially overlapped with each other, which may reduce working area and make overall integration of the semiconductor structure higher.

In the formation method of the semiconductor structure provided in technical solutions of the present disclosure, the second transistor may be at an upper layer above the first transistor; and the projections of the first transistor and the second transistor on the surface of the substrate may be non-overlapped with each other; that is, the first transistor and the second transistor may be arranged in a staggered manner along the direction in parallel with the substrate to additionally provide the space between the first transistor and the second transistor. Therefore, the parasitic capacitance between the first transistor and the second transistor may be reduced, and the device performance may be improved. Meanwhile, the staggered arrangement of the first transistor and the second transistor may provide more wiring space for the electrical connection between the first transistor and the second transistor, which may improve process window and reduce process defect.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional structural view of a transistor according to various disclosed embodiments of the present disclosure.

FIGS. 2-7 illustrate structural schematics of an exemplary semiconductor structure according to various disclosed embodiments of the present disclosure.

FIGS. 8-11 illustrate structural schematics of another exemplary semiconductor structure according to various disclosed embodiments of the present disclosure.

FIG. 12 illustrates an exemplary formation method of a semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a formation method of the semiconductor structure are provided in the present disclosure. The semiconductor structure includes a substrate, including a first device region and a second device region; a first device layer on the substrate, where a first transistor at the first device region is in the first device layer; a second device layer on the first device layer, where a second transistor at the second device region is in the second device layer, and projections of the first transistor and the second transistor on a surface of the substrate are non-overlapped with each other; and an electrical interconnection structure in the first device layer and the second device layer, where the electrical interconnection structure is electrically connected to each of the first transistor and the second transistor.

It may be known from the background that, with continuous size reduction of transistor devices, the parasitic capacitance between the transistor structures in the devices is excessively large, which has become an important factor limiting device performance.

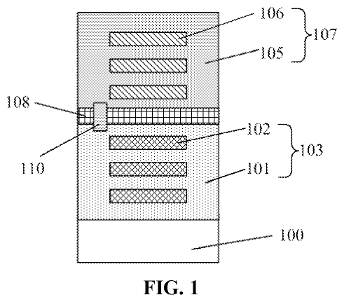

FIG. 1 illustrates a cross-sectional structural view of a transistor according to various disclosed embodiments of the present disclosure.

Referring to FIG. 1, the transistor may include a substrate 100; a first transistor 103 and a second transistor 107 on the substrate 100; and a dielectric layer 108 between the first transistor 103 and the second transistor 107. The first transistor 103 may include a plurality of first channel layers 102 overlapped with each other along the direction perpendicular to the surface of the substrate 100 and include a first gate structure 101 crossing the first channel layers 102. The first gate structure 101 may be also between the first channel layers 102. The second transistor 107 may include a plurality of second channel layers 106 overlapped with each other along the direction perpendicular to the surface of the substrate 100 and include a second gate structure 105 crossing the second channel layers 106. The second gate structure 105 may be also between the second channel layers 106. The first transistor 103 and the second transistor 107 may be stacked with each other along the direction perpendicular to the substrate 100; and the projections of the first transistor 103 and the second transistor 107 on the surface of the substrate 100 may be coincided with each other. The first transistor 103 and the second transistor 107 may be electrically connected with each other through a conductive plug 110.

In one embodiment, the first transistor 103 may be an NMOS transistor; the second transistor 107 may be a PMOS transistor.

Due to continuous size reduction of devices, the size and spacing of the first transistor 103 and the second transistor 107 may continue to decrease. Therefore, the parasitic capacitance between the first transistor 103 and the second transistor 107 which are vertically stacked with each other may be relatively large, which may further limit device performance of the transistors.

In order to solve above technical problems, the technical solutions of the present disclosure provide a semiconductor structure. The semiconductor structure may include the first transistor and the second transistor. The second transistor may be at an upper layer above the first transistor. In addition, the projections of the first transistor and the second transistor on the surface of the substrate may be non-overlapped with each other; that is, the first transistor and the second transistor may be arranged in a staggered manner along the direction in parallel with the substrate. Therefore, the space between the first transistor and the second transistor may be additionally provided, the parasitic capacitance between the first transistor and the second transistor may be reduced, thereby improving device performance. Meanwhile, the staggered arrangement of the first transistor and the second transistor may provide more wiring space for the electrical connection between the first transistor and the second transistor, which may improve process window and reduce process defect.

In order to clearly illustrate above-mentioned described objectives, features, and advantages of the present disclosure, various embodiments of the present disclosure are described in detail with reference to accompanying drawings hereinafter.

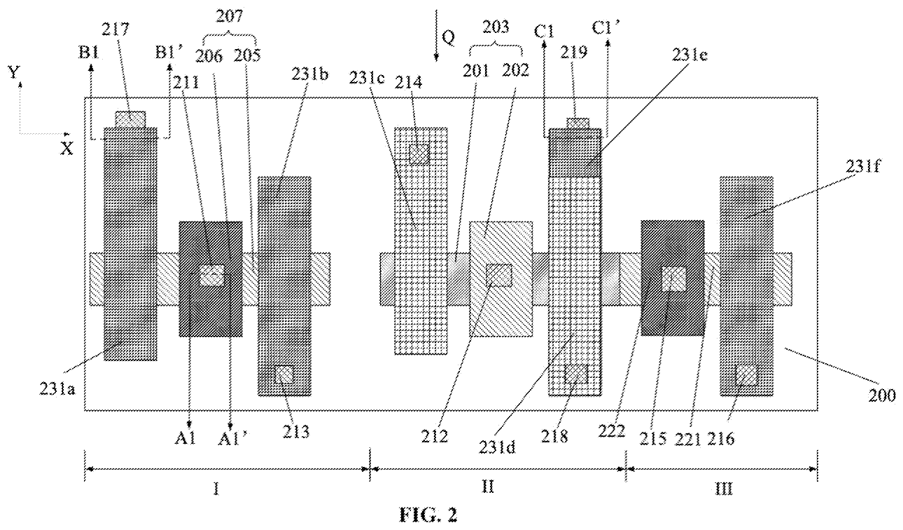

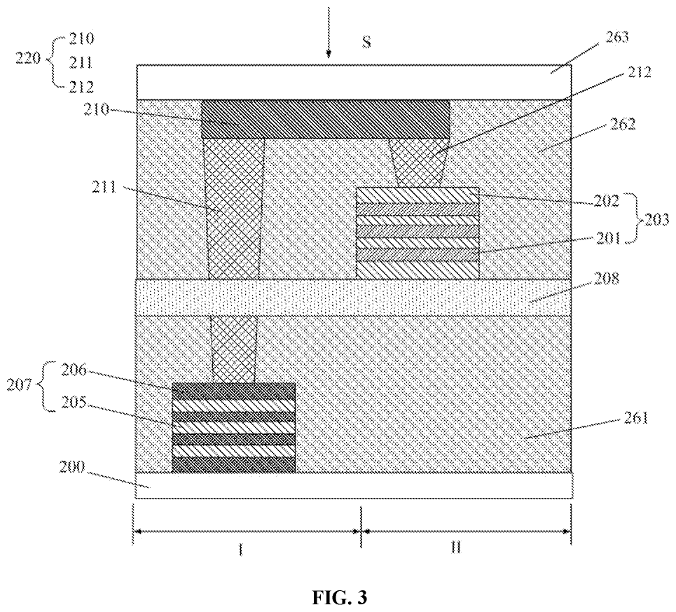

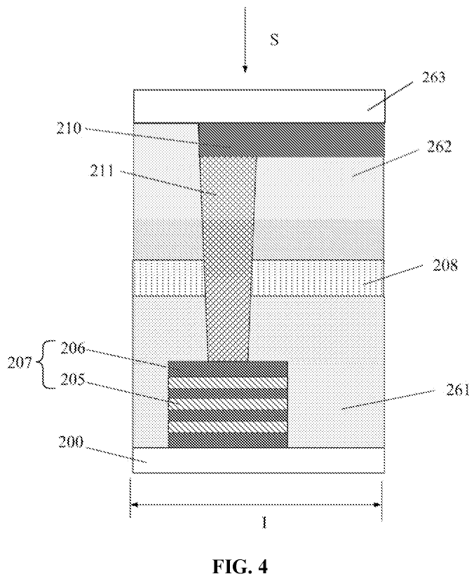

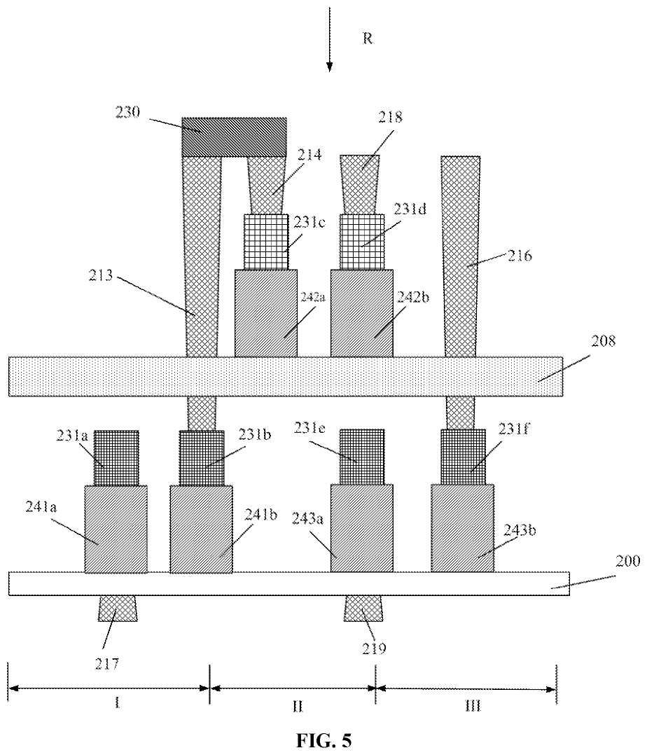

FIGS. 2-7 illustrate structural schematics of an exemplary semiconductor structure according to various disclosed embodiments of the present disclosure. FIG. 2 is a top view along an S direction in FIGS. 3-4; FIG. 2 is a top view along a R direction in FIGS. 5-7;

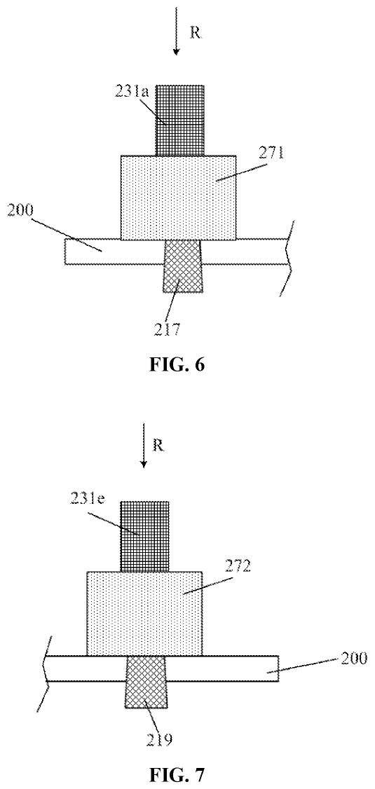

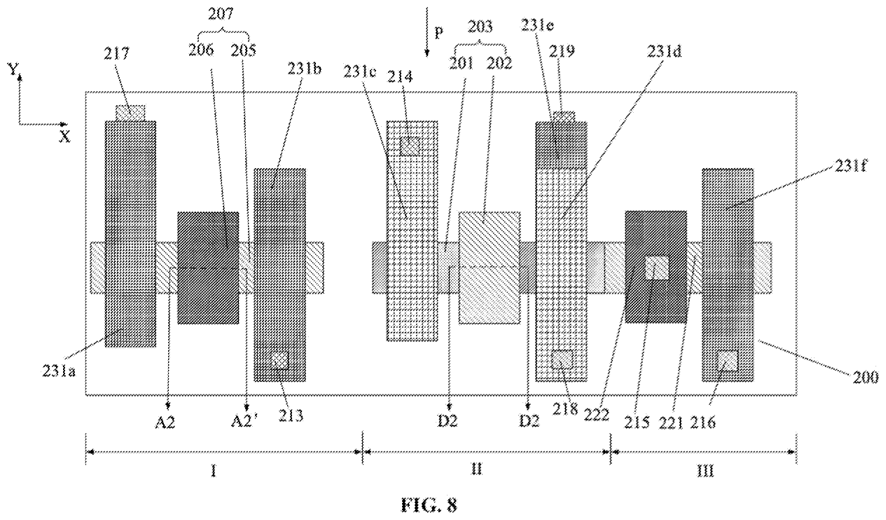

FIG. 3 is a side view of a partial region along a Q direction in FIG. 2; FIG. 4 is a partial cross-sectional view along an A1A1′ direction in FIG. 2; FIG. 5 is a side view of a partial region along a Q direction in FIG. 2; FIG. 6 is a partial cross-sectional view along a B1B1′ direction in FIG. 2; and FIG. 7 is a partial cross-sectional view along a C1C1′ direction in FIG. 2.

Referring to FIGS. 2-4, the semiconductor structure may include a substrate 200, where the substrate 200 may include a first device region I and a second device region II; a first device layer 261 on the substrate 200, where the first device layer 261 may include a first transistor 207 at the first device region I; a second device layer 262 on the first device layer 261, where the second device layer 262 may include a second transistor 203 at the second device region II, and the projections of the first transistor 207 and the second transistor 203 on the surface of the substrate 200 may be non-overlapped with each other; and an electrical interconnection structure 220 in the first device layer 261 and the second device layer 262, where the electrical interconnection structure may be electrically connected to each of the first transistor 207 and the second transistor 203.

It should be noted that FIG. 3 is a side view of the first transistor 207, the second transistor 203 and the electrical interconnection structure 220 between the first transistor 207 and the second transistor 203 along the Q direction in FIG. 2. FIG. 4 is a cross-sectional view of the first transistor 207 and a part of the electrical interconnection structure 220 along the A1A1′ direction in FIG. 2.

The substrate 200 may be made of a material including silicon, silicon germanium, silicon carbide, silicon on insulator (SOI), germanium on insulator (GOI) and the like. For example, in one embodiment, the substrate 200 may be made of silicon.

In one embodiment, the conductivity types of the first transistor 207 and the second transistor 203 may be opposite to each other. For example, the first transistor 207 may be an NMOS transistor, and the second transistor 203 may be a PMOS transistor.

In other embodiments, the first transistor 207 may be a PMOS transistor, and the second transistor 203 may be an NMOS transistor.

In one embodiment, the first transistor 207 may include a first channel structure extending along the first direction X and a first gate structure 206 extending along the second direction Y; the first gate structure 206 may be on the surface of the first channel structure; and the second direction Y may be perpendicular to the first direction X. The second transistor 203 may include a second channel structure extending along the first direction X and a second gate structure 202 extending along the second direction Y; and the second gate structure 202 may be on the surface of the second channel structure.

In one embodiment, the first channel structure may include a plurality of first channel layers 205 overlapped with each other along the direction perpendicular to the surface of the substrate 200, and the first gate structure 206 may surround the surface of each first channel layer 205; and the second channel structure may include a plurality of second channel layers 201 overlapped with each other along the direction perpendicular to the surface of the substrate 200, and the second gate structure 202 may surround the surface of each second channel layer 201. Therefore, the first transistor 207 and the second transistor 203 may be full-surround gate transistors, and the transistors may have stronger control capability over a channel current.

In another embodiment, the first channel structure and the second channel structure may be fin structures extending along the first direction; and the first gate structure and the second gate structure may be at the surfaces of the fin structures. Therefore, the first transistor and the second transistor may be fin transistors.

In one embodiment, the electrical interconnection structure 220 may include a first plug 211 on the first gate structure 206, a second plug 212 on the second gate structure 202, and a first electrical connection structure 210 electrically connected to each of the first plug 211 and the second plug 212 (as shown in FIG. 3). The first gate structure 206 and the second gate structure 202 may be electrically connected with each other through the first plug 211, the second plug 212 and the first electrical connection structure 210.

In one embodiment, a dielectric layer 208 may be between the first device layer 261 and the second device layer 262.

In one embodiment, the second transistor 203 may be at the upper layer above the first transistor 207, and the projections of the first transistor 207 and the second transistor 203 on the surface of the substrate 200 may be non-overlapped with each other, that is, the first transistor 207 and the second transistor 203 may be arranged in a staggered manner along the direction in parallel with the substrate 200. Therefore, the space between the first transistor 207 and the second transistor 203 may be additionally provided. Compared with the transistor structures vertically stacked at upper and lower layers in conventional CFET transistors, in one embodiment, the first transistor 207 and the second transistor 203 may be arranged in a staggered manner, which may effectively reduce the parasitic capacitance between the first transistor 207 and the second transistor 203 and improve device performance. Meanwhile, the staggered arrangement of the first transistor 207 and the second transistor 203 may also provide more wiring space for the electrical connection between the first transistor 207 and the second transistor 203, which may reduce wiring difficulty, improve process window and reduce process defect.

For example, in one embodiment, the spacing range between the first transistor 207 and the second transistor 203 may be from about 20 nanometers to about 100 nanometers.

In one embodiment, the substrate 200 may further include a third device region III. The semiconductor structure may further include a third transistor 209 at the third device region III in the first device layer 261; and the projections of the third transistor 209 and the second transistor 203 on the surface of the substrate 200 may be partially overlapped with each other.

In one embodiment, the first transistor 207 and the third transistor 209 may have a same structure; the first transistor 207 and the third transistor 209 may be at a same layer; and the second transistor 203 may be at the upper layer above the first transistor 207 and the third transistor 209. For example, the third transistor 209 may include a third channel structure and a third gate structure 222 crossing the third channel structure; and the third channel structure may include a plurality of third channel layers 221 overlapped with each other along the direction perpendicular to the surface of the substrate 200, and the third gate structure 222 may surround the surface of each third channel layer 221.

In one embodiment, the conductivity types of the third transistor 209 and the first transistor 207 may be same, and the third transistor 209 may be an NMOS transistor.

It should be noted that the third transistor 209 is omitted in FIG. 3 for ease of understanding.

Referring to FIGS. 3-4, the first gate structure 206 and the second gate structure 202 may be electrically connected with each other through the first plug 211, the second plug 212 and the first electrical connection structure 210.

In one embodiment, the first plug 211, the second plug 212 and the first electrical connection structure 210 may be electrically connected with each other through an upward connection manner. For example, the first electrical connection structure 210 may be in the second device layer 262; the first plug 211 may be in the first device layer 261 and the second device layer 262; and the second plug 212 may be in the second device layer 262. The first electrical connection structure 210 may be above the first transistor 207 and the second transistor 203; one end of the first plug 211 may be in contact with the first transistor 207, and the other end of the first plug 211 may be in contact with the first electrical connection structure 210; and the first plug 211 may pass through the dielectric layer 208 (as shown in FIG. 4). One end of the second plug 212 may be in contact with the second transistor 203, and the other end of the second plug 212 may be in contact with the first electrical connection structure 210. The height dimension of the first plug 211 along the direction perpendicular to the surface of the substrate 200 may be greater than the height dimension of the second plug 212 along the direction perpendicular to the surface of the substrate 200.

It should be noted that, for ease of understanding, the first electrical connection structure 210, the first device layer 261, the second device layer 262 and the dielectric layer 208 are omitted in FIG. 2.

Referring to FIG. 5, in one embodiment, the first transistor 207 may further include a first source electrode 241a and a first drain electrode 241b on two sides of the first gate structure 206; the second transistor 203 may further include a second source electrode 242a and a second drain electrode 242b on two sides of the second gate structure 202; and the third transistor 209 may further include a third source electrode 243a and a third drain electrode 243b on two sides of the third gate structure 222.

In one embodiment, the semiconductor structure may further include a first electrical contact structure 231a electrically connected to the first source electrode 241a; a second electrical contact structure 231b electrically connected to the first drain electrode 241b; a third electrical contact structure 231c electrically connected to the second source electrode 242a; a fourth electrical contact structure 231d electrically connected to the second drain electrode 242b; a fifth electrical contact structure 231e electrically connected to the third source electrode 243a; and a sixth electrical contact structure 231f is electrically connected to the third drain electrode 243b.

Referring to FIGS. 2 and 5-7, FIG. 5 is a side view along the Q direction in FIG. 2. It should be noted that, for ease of understanding, the first transistor 207, the second transistor 203, the third transistor 209 and the electrical interconnection structure 220 connecting the first transistor 207 with the second transistor 203 in FIG. 2 are omitted in FIG. 5. FIG. 6 is a partial cross-sectional view of the first electrical contact structure 231a and a first source connection plug 217 along the B1B1′ direction in FIG. 2. FIG. 7 is a partial cross-sectional view of the fifth electrical contact structure 231e and a second source connection plug 219 along the C1C1′ direction in FIG. 2.

In one embodiment, the projections of the third source electrode 243a of the third transistor 209 and the second drain electrode 242b of the second transistor 203 on the surface of the substrate 200 may be coincided with each other, such that the projections of the third transistor 209 and the second transistor 203 on the surface of the substrate 200 may be partially overlapped with each other. The projections of the fifth electrical contact structure 231e on the third source electrode 243a and the fourth electrical contact structure 231d on the second drain electrode 242b on the surface of the substrate 200 may be at least partially overlapped with each other.

In one embodiment, since the projections of the fifth electrical contact structure 231e and the fourth electrical contact structure 231d on the surface of the substrate 200 are at least partially overlapped with each other, such that the working area may be reduced, and overall integration of the semiconductor structure may be desirable.

In one embodiment, the semiconductor structure may further include a third plug 213 on the second electrical contact structure 231b, a fourth plug 214 on the third electrical contact structure 231c, and a second electrical connection structure 230 electrically connected to each of the third plug 213 and the fourth plug 214. The second electrical contact structure 231b and the third electrical contact structure 231c may be electrically connected with each other through the third plug 213, the fourth plug 214 and the second electrical connection structure 230.

In one embodiment, the third plug 213, the fourth plug 214 and the second electrical connection structure 230 may be electrically connected with each other through an upward connection manner. For example, the second electrical connection structure 230 may be in the second device layer 262; the third plug 213 may be in the first device layer (not shown in FIG. 5) and the second device layer (not shown in FIG. 5) and pass through the dielectric layer 208; and the fourth plug 214 may be in the second device layer.

In one embodiment, the height dimension of the third plug 213 along the direction perpendicular to the surface of the substrate 200 may be greater than the height dimension of the fourth plug 214 along the direction perpendicular to the surface of the substrate 200.

It should be noted that, for ease of understanding, the second electrical connection structure 230 in FIG. 5 is omitted in FIG. 2; and the first device layer 261 and the second device layer 262 are omitted in FIG. 5.

In another embodiment, the third plug, the fourth plug and the second electrical connection structure may be electrically connected with each other through a downward connection manner. The third plug may pass through the substrate; the fourth plug may pass through the dielectric layer, the first device layer and the substrate; and the second electrical connection structure may be on the surface of the substrate.

The height dimension of the third plug along the direction perpendicular to the substrate surface may be less than the height dimension of the fourth plug along the direction perpendicular to the substrate surface.

In one embodiment, the semiconductor structure may further include an upper electrical interconnection layer 263 (e.g., in FIG. 3). The upper electrical interconnection layer 263 may be on the surface of the second device layer. The upper electrical interconnection layer 263 may connect the first transistor 207, the second transistor 203, and the third transistor 209 to an external circuit.

In one embodiment, the second electrical connection structure 230 may be in the second device layer; that is, the second electrical connection structure 230 may be between the second transistor 203 and the upper electrical interconnection layer 263. The upper electrical interconnection layer 263 and the second electrical connection structure 230 may be electrically connected with each other through a seventh plug.

The second electrical connection structure 230 may be between the second transistor 203 and the upper electrical interconnection layer 263, that is, the second electrical connection structure 230 and the upper electrical interconnection layer 263 may be at different layers. Therefore, the second electrical connection structure 230 may be in an independent interconnection layer, which may increase the wiring area of the second electrical connection structure 230 and further allow the line width of the second electrical connection structure 230 to be larger, thereby reducing resistance and improving device performance.

In one embodiment, the positions of the first transistor 207, the second transistor 203, the first electrical connection structure 210 and the second electrical connection structure 230 along the second direction Y may be same or different.

In another embodiment, the second electrical connection structure may be on the surface of the second device layer, such that the second electrical connection structure and the upper electrical interconnection layer 263 may be at a same layer. Therefore, the second electrical connection structure and the upper electrical interconnection layer 263 may be formed through a same manufacturing process, thereby saving process steps and cost.

In one embodiment, the third gate structure 222 and the sixth electrical contact structure 231f may be electrically connected to the upper electrical interconnection layer 263.

For example, the semiconductor structure in one embodiment may further include a fifth plug 215 on the third gate structure 222, where the third gate structure 222 may be electrically connected to the upper electrical interconnection layer 263 through the fifth plug 215; and include a sixth plug 216 on the sixth electrical contact structure 231f, where the sixth electrical contact structure 231f may be electrically connected to the upper electrical interconnection layer 263 through the sixth plug 216. The fifth plug 215 may extend from the first device layer to the surface of the second device layer and pass through the dielectric layer 208 and the second device layer; and the sixth plug 216 may extend from the first device layer to the surface of the second device layer and pass through the dielectric layer 208 and the second device layer.

In one embodiment, the first electrical contact structure 231a on the first drain electrode 241b may be used to be connected to a source power supply Vss; and the fourth electrical contact structure 231d on the second drain electrode 242b may be used to be connected to a drain power supply Vdd.

In one embodiment, a drain connection plug 218 may be on the fourth electrical contact structure 231d; and the drain connection plug 218 may extend from the inside of the second device layer to the surface of the upper electrical interconnection layer 263 on the surface of the second device layer, such that the drain connection plug 218 may be electrically connected to the upper electrical interconnection layer 263. That is, in one embodiment, the drain connection plug 218, the fifth plug 215 and the sixth plug 216 may be all electrically connected to the upper electrical interconnection layer 263 through an upward connection manner.

In one embodiment, the first electrical contact structure 231a may be connected to the source power supply Vss through an embedded power rail 271 through a wafer backside power delivery network (BSPDN) connection manner.

Referring to FIG. 6, for example, the first electrical contact structure 231a may be electrically connected to the first source connection plug 217 through the embedded power rail 271; and the first source connection plug 217 may pass through the substrate 200 from the first device layer (not shown in FIG. 6) and extend to the surface of the substrate 200 to be connected to the source power supply Vss.

Referring to FIG. 7, similarly, the fifth electrical contact structure 231e on the third source 243a may be connected to the source power supply Vss through an embedded power rail 272 through the wafer backside power delivery network connection manner. For example, the fifth electrical contact structure 231e may be electrically connected to the second source connection plug 219 through the embedded power rail 272; and the second source connection plug 219 may pass through the substrate 200 from the first device layer (not shown in FIG. 6) and extend to the surface of the substrate 200 to be connected to the source power supply Vss.

Therefore, the first electrical contact structure 231a and the fifth electrical contact structure 231e may be connected to the source power supply Vss through the wafer backside power delivery network connection manner, which may effectively reduce wiring complexity, improve device integration and performance and reduce voltage drop of interconnection wiring.

It should be noted that, for ease of understanding, the embedded power rail 271 and the embedded power rail 272 are omitted in FIGS. 2 and 5.

In another embodiment, the semiconductor structure may further include a lower electrical interconnection layer on a surface of the substrate. The drain connection plug on the fourth electrical contact structure, the fifth plug on the third gate structure, and the sixth plug on the sixth electrical contact structure may pass through the substrate. That is, the drain connection plug, the fifth plug and the sixth plug may be electrically connected to the lower electrical interconnection layer through a downward connection manner.

In other embodiments, the drain connection plug on the fourth electrical contact structure may be electrically connected to an external electrical interconnection layer through an upward connection manner or a downward connection manner; the fifth plug on the third gate structure may be electrically connected to an external electrical interconnection layer through an upward connection manner or a downward connection manner; and the sixth plug on the sixth electrical contact structure may be electrically connected to an external electrical interconnection layer through an upward connection manner or a downward connection manner. Above-mentioned connection manners may be combined arbitrarily.

As disclosed above, in one embodiment, the projections of the first transistor 207 and the second transistor 203 above the first transistor 207 on the surface of the substrate 200 may be non-overlapped with each other; that is, the first transistor 207 and the second transistor 203 may be arranged in a staggered manner along the direction in parallel with the substrate 200. Therefore, the space between the first transistor 207 and the second transistor 203 may be additionally provided, and the parasitic capacitance between the first transistor 207 and the second transistor 203 may be reduced, thereby improving device performance. Meanwhile, staggered arrangement of the first transistor 207 and the second transistor 203 may provide more wiring space for the electrical connection between the first transistor 207 and the second transistor 203.

Based on above description, the projections of the fifth electrical contact structure 231e of the third transistor 209 and the fourth electrical contact structure 231d of the second transistor 203 on the surface of the substrate 200 may be at least partially overlapped with each other, such that the working area may be reduced, and overall integration of the semiconductor structure may be desirable.

Therefore, in one embodiment, staggered arrangement of the transistor structures may additionally provide the space between adjacent transistors, smaller parasitic capacitance and higher device integration may be achieved, which may be used for smooth transition process from gate-all-around transistors to CFET transistors and provide an important choice of transistor structures as an intermediate technology node.

In another embodiment, the first plug on the first gate structure, the second plug on the second gate structure and the first electrical connection structure may be electrically connected through a downward connection manner. FIGS. 8-11 illustrate structural schematics of another exemplary semiconductor structure according to various disclosed embodiments of the present disclosure.

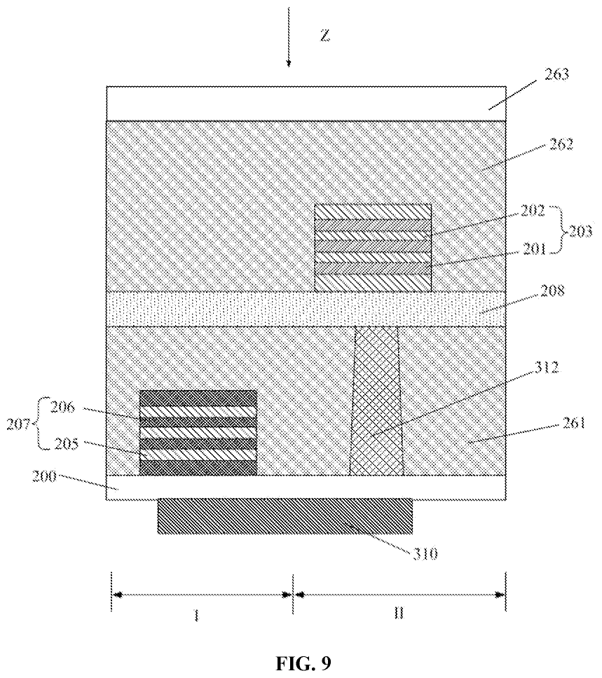

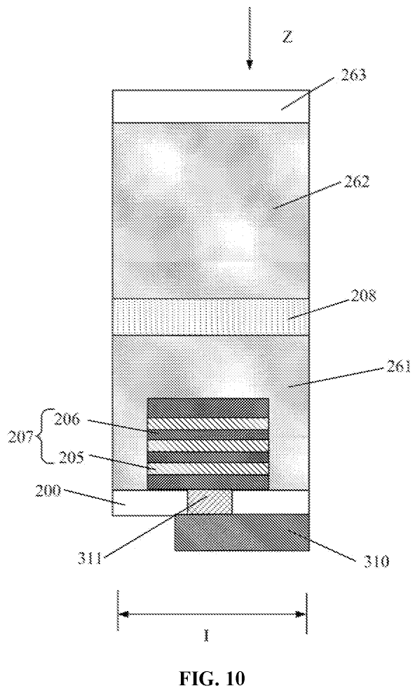

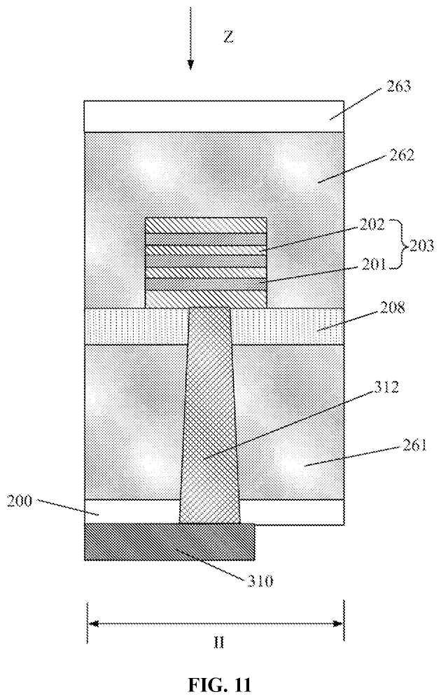

FIG. 8 is a top view along the Z direction in FIGS. 9-11. FIG. 9 is a side view along the P direction of the first transistor 207, the second transistor 203 and the electrical interconnection structure 220 between the first transistor 207 and the second transistor 203 in FIG. 8. FIG. 10 is a partial cross-sectional view of the first transistor 207 and a part of the electrical interconnection structure 220 along the A2A2′ direction in FIG. 8. FIG. 11 is a partial cross-sectional view of the second transistor 203 and a part of the electrical interconnection structure 220 along the D2D2′ direction in FIG. 8.

Referring to FIGS. 8-11, the first plug 311 may pass through the substrate 200; the second plug 312 may pass through the dielectric layer 208, the first device layer 261 and the substrate 200; and the first electrical connection structure 310 may be on the surface of the substrate 200.

The height dimension of the first plug 311 along the direction perpendicular to the surface of the substrate 200 may be less than the height dimension of the second plug 312 along the direction perpendicular to the surface of the substrate 200.

In one embodiment, the positions and electrical connection manners of other structures of the semiconductor structure may be same as the semiconductor structures in various embodiments described in FIGS. 2-7, which may not be described in detail herein.

Correspondingly, embodiments of the present disclosure further provide a formation method of above semiconductor structure.

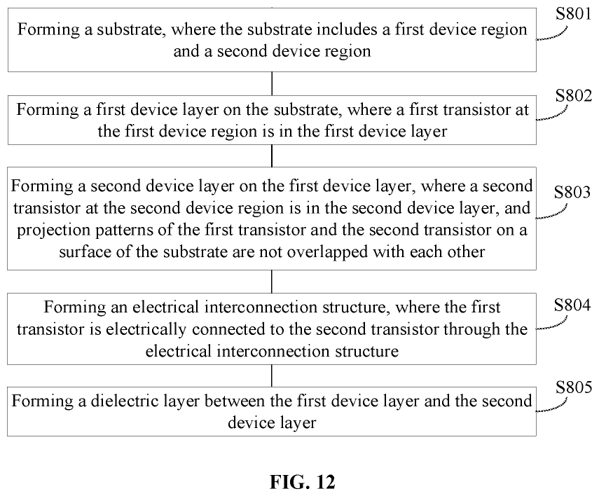

Referring to FIGS. 2-7, the formation method of the semiconductor structure may include providing the first substrate 200, where the first substrate 200 may include the first device region I, the second device region II, and the third device region III (e.g., in S801 of FIG. 12); forming the first device layer 261 on the substrate 200, where the first device layer 261 may include the first transistor 207 at the first device region I and the third transistor 209 at the third device region III (e.g., in S802 of FIG. 12); forming the dielectric layer 208 on the first device layer 261 (e.g., in S805 of FIG. 12); forming the second device layer 262 on the first device layer 261, where the second device layer 262 may include the second transistor 203 at the second device region II, the projections of the first transistor 207 and the second transistor 203 on the surface of the substrate 200 may be non-overlapped with each other, and the projections of the third transistor 209 and the second transistor 203 on the surface of the substrate 200 may be partially overlapped with each other(e.g., in S803 of FIG. 12); and forming the electrical interconnection structure 220, where the first transistor 207 and the second transistor 203 may be electrically connected with each other through the electrical interconnection structure 220 (e.g., in S804 of FIG. 12).

In one embodiment, the first transistor 207 may include the first channel structure extending along the first direction X and the first gate structure 206 extending along the second direction Y, the first gate structure 206 may be on the surface of the first channel structure, and the second direction Y may be perpendicular to the first direction X; the second transistor 203 may include the second channel structure extending along the first direction X and the second gate structure 202 extending along the second direction Y, and the second gate structure 202 may be on the surface of the second channel structure; and the third transistor 209 may include the third channel structure extending along the first direction X and the third gate structure 222 extending along the second direction Y, and the third gate structure 222 may be on the surface of the third channel structure.

In one embodiment, the first channel structure may include the plurality of first channel layers 205 overlapped with each other along the direction perpendicular to the surface of the substrate 200, and the first gate structure 206 may surround the surface of each first channel layer 205; the second channel structure may include the plurality of second channel layers 201 overlapped with each other along the direction perpendicular to the surface of the substrate 200, and the second gate structure 202 may surround the surface of each second channel layer 201; and the third channel structure may include the plurality of third channel layers 221 overlapped with each other along the direction perpendicular to the surface of the substrate 200, and the third gate structure 222 may surround the surface of each third channel layer 221. Therefore, the first transistor 207, the second transistor 203 and the third transistor 209 may be gate-all-around transistors.

In another embodiment, the first channel structure, the second channel structure and the third channel structure may be fin structures extending along the first direction; and the first gate structure, the second gate structure and the third gate structure may be on the surfaces of the fin structures. Therefore, the first, second and third transistor 209s may be fin transistors.

In one embodiment, after the first device layer 261 is formed, the dielectric layer 208 and the second device layer 262 may be formed directly on the first device layer 261.

In another embodiment, after forming the first device layer, forming the second device layer may include providing a second substrate, where the second substrate may include the first and second sides opposite to each other; forming the second device layer on the first surface, where the second transistor may be in the second device layer; after forming the second device layer, bonding the first side with the first device layer, such that the second transistor may be at the second device region of the first substrate; and after bonding the first side with the first device layer, removing the second substrate.

Forming the dielectric layer may include before bonding the first side with the first device layer, forming an initial bonding layer on the surface of one or both of the first device layer and the second device layer; and after bonding the first side with the first device layer, forming a bonding dielectric layer between the first device layer and the second device layer from the initial bonding layer.

In one embodiment, the second transistor 203 may be formed at the upper layer above the first transistor 207; and the projections of the first transistor 207 and the second transistor 203 on the surface of the substrate 200 may be non-overlapped with each other, that is, the first transistor 207 and the second transistor 203 may be arranged along the direction in parallel with the substrate 200 to additionally provide the space therebetween. Therefore, the parasitic capacitance between the first transistor 207 and the second transistor 203 may be reduced, and device performance may be improved.

In one embodiment, the electrical interconnection structure 220 connecting the first transistor 207 and the second transistor 203 may include the first plug 211 on the first gate structure 206, the second plug 212 on the second gate structure 202, and the first electrical connection structure 210 electrically connected to each of the first plug 211 and the second plug 212. The first gate structure 206 and the second gate structure 202 may be electrically connected to each other through the first plug 211, the second plug 212 and the first electrical connection structure 210.

For example, forming the electrical interconnection structure 220 may include forming the first plug 211 in the first device layer 261, the second device layer 262 and the dielectric layer 208 on the first transistor 207; forming the second plug 212 in the second device layer 262 on the second transistor 203; forming the first electrical connection structure 210 in the second device layer 262. In such way, the first plug 211, the second plug 212 and the first electrical connection structure 210 may be electrically connected with each other through an upward connection manner.

Since staggered arrangement of the first transistor 207 and the second transistor 203 provides more wiring space for the electrical connection between the first transistor 207 and the second transistor 203, the difficulty of the formation process of the first plug 211 and the second plug 212 may be reduced, which may reduce wiring difficulty, improve process window and reduce process defect.

Referring to FIGS. 2 and 5-7, in one embodiment, the first transistor 207 may further include the first source electrode 241a and the first drain electrode 241b on two sides of the first gate structure 206; the second transistor 203 may further include the second source electrode 242a and the second drain electrode 242b on two sides of the second gate structure 202; and the third transistor 209 may include the third channel structure, the third gate structure 222 crossing the third channel structure, and the third source electrode 243a and the third drain electrode 243b on two sides of the third gate structure 222.

In one embodiment, forming the semiconductor structure may further include forming the first electrical contact structure 231a on the first source electrode 241a; forming the second electrical contact structure 231b on the first drain electrode 241b; forming the third electrical contact structure 231c on the second source electrode 242a; forming the fourth electrical contact structure 231d on the second drain electrode 242b; forming the fifth electrical contact structure 231e on the third source electrode 243a; and forming the sixth electrical contact structure 231f on the third drain electrode 243b. The projections of the fifth electrical contact structure 231e and the fourth electrical contact structure 231d on the surface of the substrate 200 may be at least partially overlapped with each other.

In one embodiment, forming the semiconductor structure may further include forming the third plug 213 on the second electrical contact structure 231b, forming the fourth plug 214 on the third electrical contact structure 231c and forming the second electrical connection structure 230 electrically connected to each of the third plug 213 and the fourth plug 214. The second electrical contact structure 231b and the third electrical contact structure 231c may be electrically connected with each other through the third plug 213, the fourth plug 214 and the second electrical connection structure 230.

In one embodiment, specific positions of the third plug 213, the fourth plug 214 and the second electrical connection structure 230 refer to the description described above, which may not be described in detail herein.

In one embodiment, forming the semiconductor structure may further include forming the upper electrical interconnection layer 263 on the surface of the second device layer 262. The positional relationship and electrical connection relationship between the second electrical connection structure 230 and the upper electrical interconnection layer 263 refer to the description described above, which may not be described in detail herein.

In one embodiment, the fifth plug 215 on the third gate structure 222 may be formed when the first plug 211 is formed; the sixth plug 216 on the sixth electrical contact structure 231f may be formed when the third plug 213 is formed; and the third gate structure 222 may be electrically connected to the upper electrical interconnection layer 263 through the fifth plug 215, and the sixth electrical contact structure 231f may be electrically connected to the upper electrical interconnection layer 263 through the sixth plug 216.

In one embodiment, forming the semiconductor structure may further include forming the drain connection plug 218 on the fourth electrical contact structure 231d. The drain connection plug 218 may be in contact with the upper electrical interconnection layer 263 to be connected to the drain power supply Vdd.

In one embodiment, the formation method of the semiconductor structure may further include forming the first source connection plug 217 passing through the substrate 200, where the first electrical contact structure 231a may be electrically connected to the first source connection plug 217 through the embedded power rail 271; and forming the second source connection plug 219 passing through the substrate 200, where the fifth electrical contact structure 231e may be electrically connected to the second source connection plug 219 through the embedded power rail 272. The first source connection plug 217 and the second source connection plug 219 may pass through the substrate 200 from the first device layer and extend to the surface of the substrate 200 to be connected to the source power supply Vss.

Specific positional relationship and electrical connection relationship between the drain connection plug 218, the first source connection plug 217, the second source connection plug 219, the fifth plug 215, the sixth plug 216 and the upper electrical interconnection layer 263 refer to the description as described above, which may not be described in detail herein.

Referring to FIGS. 8-11, in another embodiment, the first plug 311, the second plug 312 and the first electrical connection structure 310 may be electrically connected with each other through a downward connection manner. The first plug 311 may pass through the substrate 200; the second plug 312 may pass through the dielectric layer 208, the first device layer 261 and the substrate 200; and the first electrical connection structure 310 may be on the surface of the substrate 200.

Although the present disclosure has been disclosed above, the present disclosure is not limited thereto. Any changes and modifications may be made by those skilled in the art without departing from the spirit and scope of the disclosure, and the scope of the disclosure should be determined by the scope defined by the appended claims.

What is claimed is:

1. A semiconductor structure, comprising:
a substrate, including a first device region and a second device region.
a first device layer on the substrate, wherein a first transistor at the first device region is in the first device layer;
a second device layer on the first device layer, wherein a second transistor at the second device region is in the second device layer, and projections of the first transistor and the second transistor on a surface of the substrate are non-overlapped with each other; and
an electrical interconnection structure in the first device layer and the second device layer, wherein the electrical interconnection structure is electrically connected to each of the first transistor and the second transistor.

2. The semiconductor structure according to claim 1, wherein:
a conductivity type of the first transistor is opposite to a conductivity type of the second transistor;
the first transistor is an N-channel metal-oxide semiconductor (NMOS) transistor, and the second transistor is a P-channel metal-oxide semiconductor (PMOS) transistor; and/or
a spacing range between the first transistor and the second transistor is from about 20 nanometers to about 100 nanometers.

3. The semiconductor structure according to claim 1, wherein:
the first transistor includes a first channel structure extending along a first direction and a first gate structure extending along a second direction; the first gate structure is on a surface of the first channel structure; and the second direction is perpendicular to the first direction; and
the second transistor includes a second channel structure extending along the first direction and a second gate structure extending along the second direction; and the second gate structure is on a surface of the second channel structure.

4. The semiconductor structure according to claim 3, wherein:
the first channel structure includes a plurality of first channel layers overlapped with each other along a direction perpendicular to the surface of the substrate, and the first gate structure surrounds a surface of each first channel layer; and the second channel structure includes a plurality of second channel layers overlapped with each other along the direction perpendicular to the surface of the substrate, and the second gate structure surrounds a surface of each second channel layer; and/or
the electrical interconnection structure includes a first plug on the first gate structure, a second plug on the second gate structure, and a first electrical connection structure electrically connected to each of the first plug and the second plug; and the first gate structure and the second gate structure are electrically connected with each other through the first plug, the second plug and the first electrical connection structure.

5. The semiconductor structure according to claim 4, wherein:
the first electrical connection structure is in the second device layer; the first plug is in the first device layer and the second device layer; and the second plug is in the second device layer; and/or
the first plug passes through the substrate, the second plug passes through the first device layer and the substrate, and the first electrical connection structure is on the surface of the substrate.

6. The semiconductor structure according to claim 3, wherein:
the first transistor further includes a first source electrode and a first drain electrode on two sides of the first gate structure; and the second transistor further includes a second source electrode and a second drain electrode on two sides of the second gate structure.

7. The semiconductor structure according to claim 6, further including:
a first electrical contact structure electrically connected to the first source electrode; a second electrical contact structure electrically connected to the first drain electrode; a third electrical contact structure electrically connected to the second source electrode; and a fourth electrical contact structure electrically connected to the second drain electrode; and/or
a third plug on the second electrical contact structure, a fourth plug on the third electrical contact structure, and a second electrical connection structure electrically connected to each of the third plug and the fourth plug, wherein the second electrical contact structure and the third electrical contact structure are electrically connected with each other through the third plug, the fourth plug and the second electrical connection structure.

8. The semiconductor structure according to claim 7, wherein:
the second electrical connection structure is in the second device layer, the third plug is in the first device layer and the second device layer, and the fourth plug is in the second device layer; and/or
the third plug passes through the substrate, the fourth plug passes through the first device layer and the substrate, and the second electrical connection structure is on the surface of the substrate.

9. The semiconductor structure according to claim 7, further including:
an upper electrical interconnection layer on a surface of the second device layer.

10. The semiconductor structure according to claim 9, wherein:
the second electrical connection structure is in the second device layer, and the upper electrical interconnection layer is electrically connected to the second electrical connection structure through a seventh plug; or
the second electrical connection structure is on the surface of the second device layer.

11. The semiconductor structure according to claim 7, further including:
a source connection plug passing through the substrate, wherein the first electrical contact structure is electrically connected to the source connection plug through an embedded power rail.

12. The semiconductor structure according to claim 7, wherein:
the substrate further includes a third device region; and the semiconductor structure further includes a third transistor at the third device region and in the first device layer, wherein projections of the third transistor and the second transistor on the surface of the substrate are partially overlapped with each other; and/or
the third transistor includes a third channel structure and a third gate structure crossing the third channel structure; and a third source electrode and a third drain electrode on two sides of the third gate electrode structure; and/or
a conductivity type of the third transistor is same as a conductivity type of the first transistor.

13. The semiconductor structure according to claim 12, further including:
a fifth electrical contact structure electrically connected to the third source electrode; and
a sixth electrical contact structure electrically connected to the third drain electrode, wherein:
projections of the fifth electrical contact structure and the fourth electrical contact structure on the substrate surface are at least partially overlapped with each other.

14. The semiconductor structure according to claim 13, further including:
an upper electrical interconnection layer; a fifth plug on the third gate structure, wherein the third gate structure is electrically connected to the upper electrical interconnection layer through the fifth plug; and a sixth plug is on the sixth electrical contact structure, wherein the sixth electrical contact structure is electrically connected to the upper electrical interconnection layer through the sixth plug; and/or
a source connection plug passing through the substrate, wherein the fifth electrical contact structure is electrically connected to the source connection plug through an embedded power rail.

15. The semiconductor structure according to claim 1, further including:
a dielectric layer between the first device layer and the second device layer.

16. A formation method of a semiconductor structure, comprising:
forming a substrate, wherein the substrate includes a first device region and a second device region;
forming a first device layer on the substrate, wherein a first transistor at the first device region is in the first device layer;
forming a second device layer on the first device layer, wherein a second transistor at the second device region is in the second device layer, and projections of the first transistor and the second transistor on a surface of the substrate are non-overlapped with each other;
forming an electrical interconnection structure, wherein the first transistor is electrically connected to the second transistor through the electrical interconnection structure; and
forming a dielectric layer between the first device layer and the second device layer.

17. The formation method according to claim 16, wherein forming the second device layer includes:
providing a second substrate, wherein the second substrate includes a first surface and a second surface which are opposite to each other;
forming the second device layer on the first surface, wherein the second transistor is in the second device layer;
after forming the second device layer, bonding the first side with the first device layer, such that the second transistor is at the second device region of the first substrate; and
after bonding the first side with the first device layer, removing the second substrate.

18. The formation method according to claim 17, wherein:
an initial bonding layer is formed on a surface of one of the first device layer and the second device layer or surfaces of both the first device layer and the second device layer; and
after bonding the first side with the first device layer, the initial bonding layer forms a bonding dielectric layer between the first device layer and the second device layer.

19. The formation method according to claim 16, wherein:
the first transistor includes a first channel structure extending along a first direction and a first gate structure extending along a second direction; the first gate structure is on a surface of the first channel structure; and the second direction is perpendicular to the first direction; and
the second transistor includes a second channel structure extending along the first direction and a second gate structure extending along the second direction; and the second gate structure is on a surface of the second channel structure.

20. The formation method according to claim 19, wherein:
the first channel structure includes a plurality of first channel layers overlapped with each other along a direction perpendicular to the surface of the substrate, and the first gate structure surrounds a surface of each first channel layer; and
the second channel structure includes a plurality of second channel layers overlapped with each other along the direction perpendicular to the surface of the substrate, and the second gate structure surrounds a surface of each second channel layer.
